(19) United States
(12) Patent Application Publication
(10) Pub. No.: US 2025/0044910 A1
(43) Pub. Date: Feb. 6, 2025

(54) METHOD OF PRESENTING STRUCTURED DIGITIZED ZONING DATA VIA AN APPLICATION PROGRAMMING INTERFACE TO GENERATIVE ARCHITECTURE MODEL SOFTWARE

(71) Applicant: Zoneomics Incorporated, Boca Raton, FL (US)

(72) Inventors: Matthew Player, Boca Raton, FL (US); Asim Mushtaq, Dubai (AE); Fahad Abdullah Munir, Islamabad (PK)

(21) Appl. No.: 18/765,173

(22) Filed: Jul. 5, 2024

Related U.S. Application Data
(60) Provisional application No. 63/525,648, filed on Jul. 7, 2023.

(51) Int. Cl. G06F 3/04815; G06T 17/00

(52) U.S. Cl. CPC G06F 3/04815; G06T 17/00

(57) ABSTRACT

A method presents structured digitized zoning data, by a server including a processor and a memory, via an application programming interface (API) to a client computer for displaying three-dimensional (3D) representations of geospatial data generated by generative architecture model software on a graphical user interface (GUI) on the client computer. The method includes extracting from a zoning data record, by the processor, as a function of the zoning restriction request and as a function of a default and/or a conditional zoning use class, the zoning restriction attributes associated with the zone and the zoning restriction parameters for the zoning restriction attributes by retrieving, from the zoning data record, the zoning restriction attributes associated with the zone in the zoning data record and each zoning restriction parameter for the default and/or conditional zoning use class associated with the zoning restriction attributes in the zoning data record; packaging, by the processor, the extracted zoning restriction attributes and zoning restriction parameters into a data object in a predefined data exchange format associated with the API; and transmitting, by the processor, the data object, as an API response, to the generative architecture model software to generate a visual representation of the extracted zoning restriction parameters on the GUI on the client computer.

This disclosure generally relates to providing digitized zoning data via an application programming interface to generative architecture model software.

### BACKGROUND

Currently, existing digital zoning data providers do not output data in a data structure that can be input into generative architecture model software for displaying three-dimensional (3D) representations of geospatial data. The data from existing digital zoning data providers is output in a manner that provides too much optionality and cannot be directly usable by such generative architecture model software.

### SUMMARY

An object of the present disclosure is to provide a server that is configured to output data in a data structure that can be input into generative architecture model software.

A method is provided of presenting structured digitized zoning data, by a server including a processor and a memory, via an application programming interface (API) to a client computer for displaying three-dimensional (3D) representations of geospatial data generated by generative architecture model software on a graphical user interface (GUI) on the client computer. The method includes receiving, by the server and via the API, a zoning restrictions request from the client computer generated by a user interacting with the GUI displayed on the client computer by the generative architecture model software, the zoning restrictions request including a selected geographic area; accessing, by the processor, a zoning data record, from a zoning record database in the memory, associated with the selected geographic area, the zoning data record associating a zone in which the selected geographic area is located with zoning restriction attributes limiting real estate development within the zone, the zoning data record further associating the zoning restriction attributes with zoning use class information for the zone and zoning restriction parameters for the zoning restriction attributes; and extracting from the zoning data record, by the processor, as a function of the zoning restriction request and as a function of a default and/or a conditional zoning use class, the zoning restriction attributes associated with the zone and the zoning restriction parameters for the zoning restriction attributes by retrieving, from the zoning data record, the zoning restriction attributes associated with the zone in the zoning data record and each zoning restriction parameter for the default and/or conditional zoning use class associated with the zoning restriction attributes in the zoning data record; packaging, by the processor, the extracted zoning restriction attributes and zoning restriction parameters into a data object in a predefined data exchange format associated with the API; and transmitting, by the processor, the data object, as an API response, to the generative architecture model software to generate a visual representation of the extracted zoning restriction parameters on the GUI on the client computer.

In examples, the method further includes receiving, by the server and via the API, a 3D model request from the client computer generated by the user interacting with the GUI displayed on the client computer by the generative architecture model software, the 3D model request including a request for a 3D model of a building envelope delimited by the zoning restriction parameters for the selected geographic area; and processing the received 3D model request, by the processor, and transmitting the requested 3D model of the building envelope to the generative architecture model software to generate a 3D geospatial data layer on the GUI displayed on the client computer on a 3D geospatial representation of the selected geographic area.

In examples, the zoning restriction parameters delimiting the building envelope are for zoning restriction attributes defining a height of the building envelope, a width of the building envelope, a depth of the building envelope and an area of the building envelope.

In examples, the zoning restriction attributes defining a depth of the building envelope include zoning restriction attributes selected from a group consisting of a setback from a front lot line and a setback from a rear lot line, the zoning restriction attributes defining a width of the building envelope include zoning restriction attributes selected from a group consisting of a side setback from a side lot line, and a minimum lot width, the zoning restriction attributes defining a height of the building envelope include zoning restriction attributes selected from a group consisting of a maximum building height, and a maximum floor area ratio, the zoning restriction attributes defining an area of the building envelope include zoning restriction attributes selected from a group consisting of a minimum lot size, a maximum lot coverage, a maximum impervious coverage, a minimum landscaped space and a minimum open space.

In examples, the receiving of the 3D model request includes receiving, by the server, as part of the 3D model request, the relevant zoning restriction parameters delimiting the building envelope, as transmitted to the generative architecture model software in the data object, or as further modified by the user of the client computer via the GUI.

In examples, the receiving of the received 3D model request includes receiving, by the server, as part of the 3D model request, the selected geographic area.

In examples, the selected geographic area is in the form of geospatial boundary coordinates and a geospatial origin coordinate, the processing of the received 3D model request including transforming the geospatial boundary coordinates to local coordinates.

In examples, the receiving of the zoning restrictions request from the client computer includes receiving geospatial boundary coordinates for the selected geographic area.

In examples, the geospatial coordinates are generated by the user drawing a polygon on a 3D geospatial representation of a geographic region displayed by the generative architecture model software on the GUI or by selecting a real estate parcel displayed on the 3D geospatial representation of a geographic region.

In examples, the accessing of the zoning data record associated with the selected geographic area includes: identifying, by the processor, the zone, from amongst a plurality of zones in the memory, having a boundary defined by geospatial boundary coordinates in which the received boundary geospatial coordinates for the selected geographic area are located; and accessing the zoning data record associated with the zone in the memory.

In examples, the extracting of the zoning restriction parameters includes identifying, from amongst a plurality of zoning restriction parameters corresponding to the zoning restriction attributes, the zoning restriction parameters applicable to the zoning use class associated with the selected geographic area for the zoning restriction attributes.

In examples, the zoning data record is in a nested format in which each zoning restriction attribute is a parent element and all of the zoning use classes and the zoning restriction parameters applicable to the zoning use class associated with the selected geographic area for the zoning restriction attributes are stored as child elements of the respective zoning restriction attribute.

In examples, the extracting includes filtering through each zoning restriction attribute and finds the child elements associated with the selected conditional zoning use class.

In examples, the extracting from the zoning data record, by the processor, is performed as a function of the default zoning use class, the method further including: sending, by the server and via the API, conditional zoning use class associated with the selected geographic area for display on the GUI of the client computer; receiving, by the server and via the API, a selection of the one of the conditional zoning use class by the user of the client computer via the GUI; extracting from the zoning data record, by the processor, as a function of the zoning restriction request and as a function of the selected conditional zoning use class, the zoning restriction attributes associated with the zone and conditional zoning restriction parameters for the zoning restriction attributes by retrieving, from the zoning data record, the zoning restriction attributes associated with the zone in the zoning data record and each conditional zoning restriction parameter for the conditional zoning use class associated with the zoning restriction attributes in the zoning data record; packaging, by the processor, the conditional extracted zoning restriction parameters into a further data object in the predefined data exchange format associated with the API; and transmitting, by the processor, the further data object, as an API response, to the generative architecture model software to generate a visual representation of the conditional extracted zoning restriction parameters on the GUI on the client computer.

A server for presenting structured digitized zoning data, by a server including a processor and a memory, via an application programming interface (API) to a client computer for displaying three-dimensional (3D) representations of geospatial data generated by generative architecture model software on a graphical user interface (GUI) on the client computer is also provided. The server includes at least one processor; and a memory coupled to the at least one processor. The memory includes software instructions executable by the at least one processor to: receive, via the API, a zoning controls request from the client computer generated by a user interacting with the GUI displayed on the client computer by the generative architecture model software, the zoning controls request including a selected geographic area; access a zoning data record, from a zoning record database in the memory, associated with the selected geographic area, the zoning data record associating a zone in which the selected geographic area is located with zoning restriction attributes limiting real estate development within the zone, the zoning data record further associating the zoning restriction attributes with zoning use class information for the zone and zoning restriction parameters for the zoning restriction attributes; and extract from the zoning data record, as a function of the zoning restriction request and as a function of a default and/or a conditional zoning use class, the zoning restriction attributes associated with the zone and the zoning restriction parameters for the zoning restriction attributes by retrieving, from the zoning data record, the zoning restriction attributes associated with the zone in the zoning data record and each zoning restriction parameter for the default and/or conditional zoning use class associated with the zoning restriction attributes in the zoning data record; package the extracted zoning restriction parameters into a data object in a predefined data exchange format associated with the API; and transmit the data object, as an API response, to the generative architecture model software to generate a visual representation of the extracted zoning restriction parameters on the GUI on the client computer.

In examples, the memory includes software instructions executable by the at least one processor to: receive, via the API, a 3D model request from the client computer generated by the user interacting with the GUI displayed on the client computer by the generative architecture model software, the 3D model request including a request for a 3D model of a building envelope delimited by the relevant zoning restriction parameters for the selected geographic area; and process the received 3D model request and transmit the requested 3D model of the building envelope to the generative architecture model software to generate a 3D geospatial data layer on the GUI displayed on the client computer on a 3D geospatial representation of the selected geographic area.

A method of presenting structured digitized zoning data via an application programming interface to generative architecture model software is also provided. The method includes receiving, via the application programming interface, a request from the generative architecture model software including a selected geographic location; processing the request, via a computer processor, by: mapping to the location information to a data record including zoning restriction attributes and a zoning use class associated with the selected geographic location; and identifying, from amongst a plurality of zoning restriction parameters, a zoning restriction parameter applicable to the zoning use class associated with the area information for each of the zoning restriction attributes; and generating a 3D design model based on the zoning restriction parameters to be displayed via a graphical user interface.

A non-transitory computer-readable media is also provided that stores computer-executable instructions that, when executed on a processor, cause the processor to perform the method.

### BRIEF SUMMARY OF THE DRAWINGS

FIG. 1 shows a generative computer system including a zoning data providing server that is configured to output data in a data structure that can be input into generative architecture model software;

FIG. 2 shows a of presenting structured digitized zoning data;

FIG. 3a shows an exemplary GUI displayed by THE generative architecture model software on a client computer for displaying 3D map representations of geospatial data on the GUI;

FIG. 3b illustrates a user of the client computer drawing a polygon onto the 3D map shown in FIG. 3a;

FIG. 3c illustrates a conditional zoning use class being selected via a class section window of the GUI shown in FIG. 3a;

FIG. 3d illustrates a 3D building envelope model being rendered on the map of the GUI shown in FIG. 3a;

FIG. 3e illustrates the 3D building envelope model remaining on the GUI 300 while the user modifies features of a 3D building model on the map.

FIG. 4 illustrates a method of generating digitized zoning data from government zone maps;

FIG. 5 illustrates a method of generating the digitized zoning data from government zone codes; and

FIG. 6 illustrates an example zoning data record format.

### DETAILED DESCRIPTION

Currently zoning database systems have the issue of multiple restriction standards applying to a property and or zone and they cannot generate outputs that are usable by generative architecture model software in the form of Computer-Aided Design (CAD) and/or Building Information Modeling (BIM) models, which need the correct standard to be provided in order to run on-demand automotive building design models, with no human input. However, the zoning databases are non-standard and if, for a zoning restriction attribute (e.g., maximum building height), there are multiple use classes (e.g., single family dwelling, two family dwelling, multi-family dwelling) each with a different zoning restriction parameters (e.g., 35 feet for single family dwelling, 45 feet for two family dwelling, 50 feet for multi-family dwelling), the data records auto-generated by the zoning database providers simply include all of the values for every use class or include the value STF, which means “see text field.” Human input is thus required to determine which zoning restriction applies to the allotment or project area, and zoning database systems cannot integrate their auto-generated outputs into generative architecture model software. It is thus impractical to use current zoning database systems because automated design based on the outputs of current zoning database provides is not possible.

The system and method of the present disclosure provide a new data structure and protocol that allows automated processes to be built from the data and to interact with the data. With this structure generative architecture model software is able to automatically obtain the correct zoning restriction that applies to the allotment or project area, and 3D building envelopes can be generated.

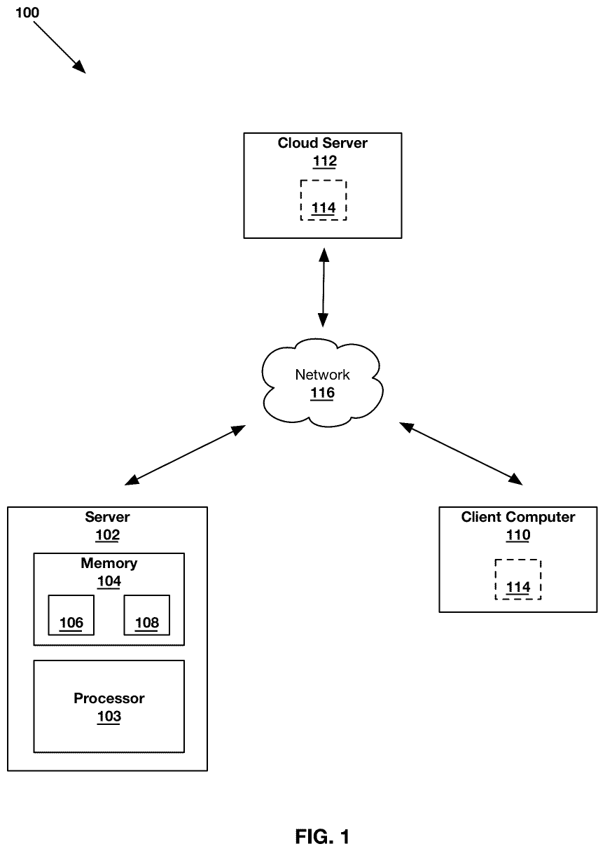

FIG. 1 shows a generative computer system 100 including a zoning data providing server 102 configured for receiving inputs including a selected geographic area and conditional zoning use class information, and configured for outputting zoning restriction attributes, corresponding to the selected geographic area and the conditional zoning use class information, in a data format that is directly usable by generative architecture model software 114. As described further below, the zoning restriction attributes and zoning use class information are extracted from municipal zoning codes that regulate how real estate can be developed in different zones within the municipality. Server 102 is also configured to output either (1) zoning restriction attributes as a 3D geospatial building envelope data object directly usable by generative architecture model software 114 to display a 3D building envelope representation on geospatial coordinates corresponding to submitted location information, or (2) zoning restriction attributes as building envelope data object formatted to be directly usable by generative architecture model software 114 to generate a 3D geospatial building envelope data object for displaying a 3D building envelope representation on geospatial coordinates corresponding to submitted location information.

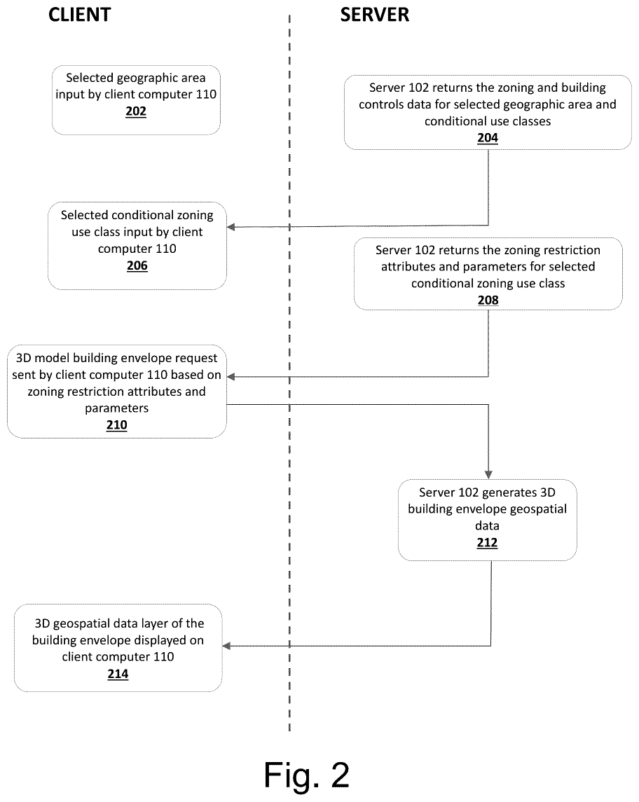

Backend server 102 is configured for receiving requests via an application program interface (API) from generative architecture model software 114 being displayed on a client computer 110, and in response, automatically generating zoning restriction attributes. The generative architecture model software 114 can run on the client computer 110 or can run on a cloud server 112 and be accessed from the cloud server 112 via a network 116, which can be the internet. As described further below, if no conditional zoning use class information is provided by the client computer, the server 102 can generate default zoning restriction attributes. The generative architecture model software 114 can be a CAD and/or BIM software program. The server 102 includes at least one processor 103 and a memory 104 coupled to the processor 103. The memory 104 includes software instructions 106 executable by the processor 103 to perform specific functions associated with API endpoints and a zoning record database 108 that is accessed by the processor 103 based on software instructions 106 to generate default and conditional zoning restriction attributes, according to whether an API call received from a generative artificial intelligence architecture model client computer 110 specifies a conditional zoning use class. In other words, the processor 103 automatically generates default zoning restriction attributes for transmission to client computer 110 when a selected geographic area is submitted by the client computer 110 without a conditional zoning use class, and processor 103 extracts conditional zoning restriction attributes for transmission to client computer 110 when a selected geographic area is submitted by the client computer 110 with a conditional zoning use class. Memory 104 includes software instructions for performing a method 200 shown in FIG. 2.

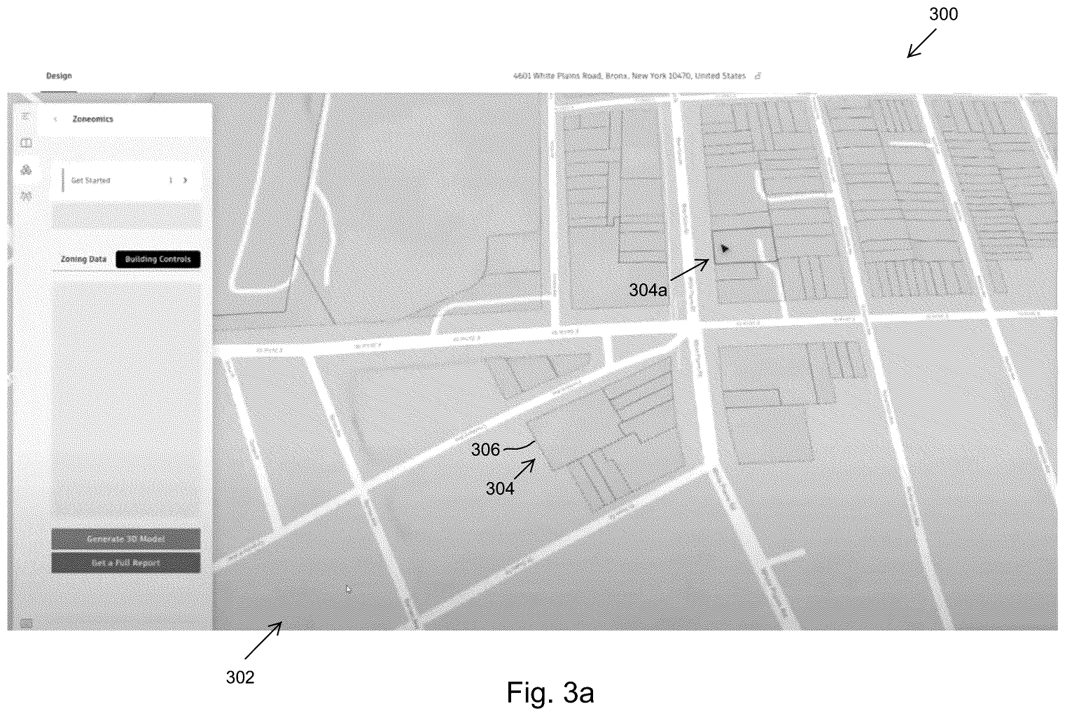

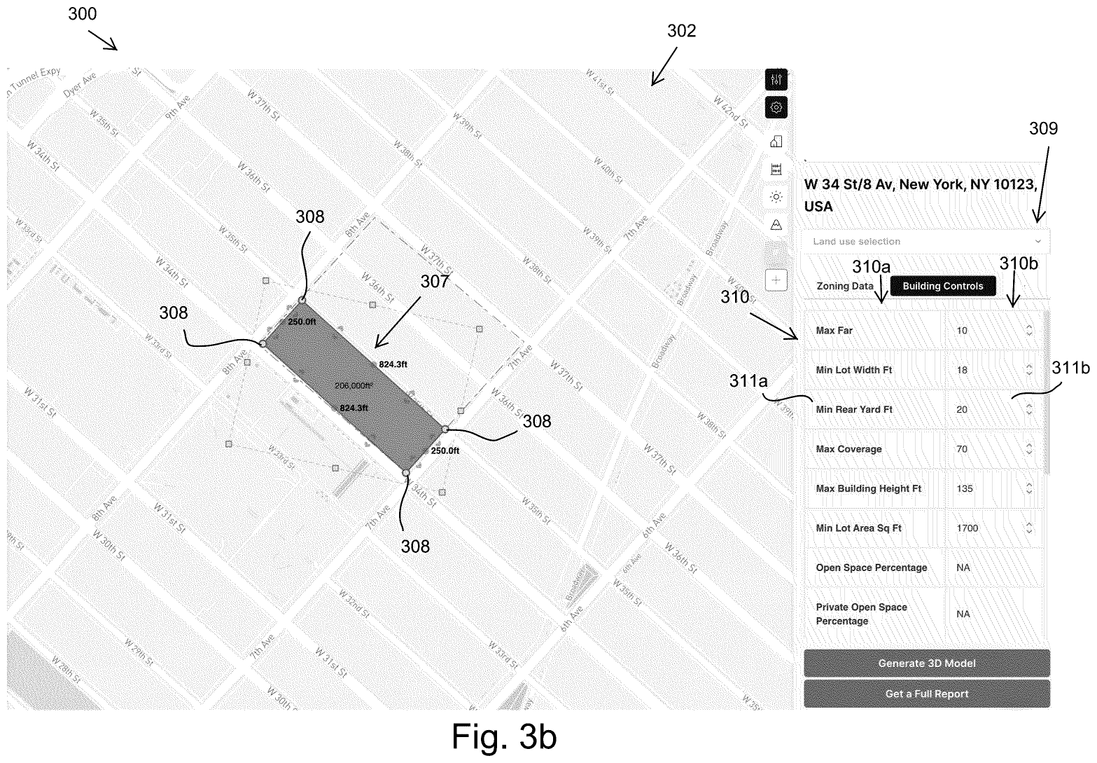

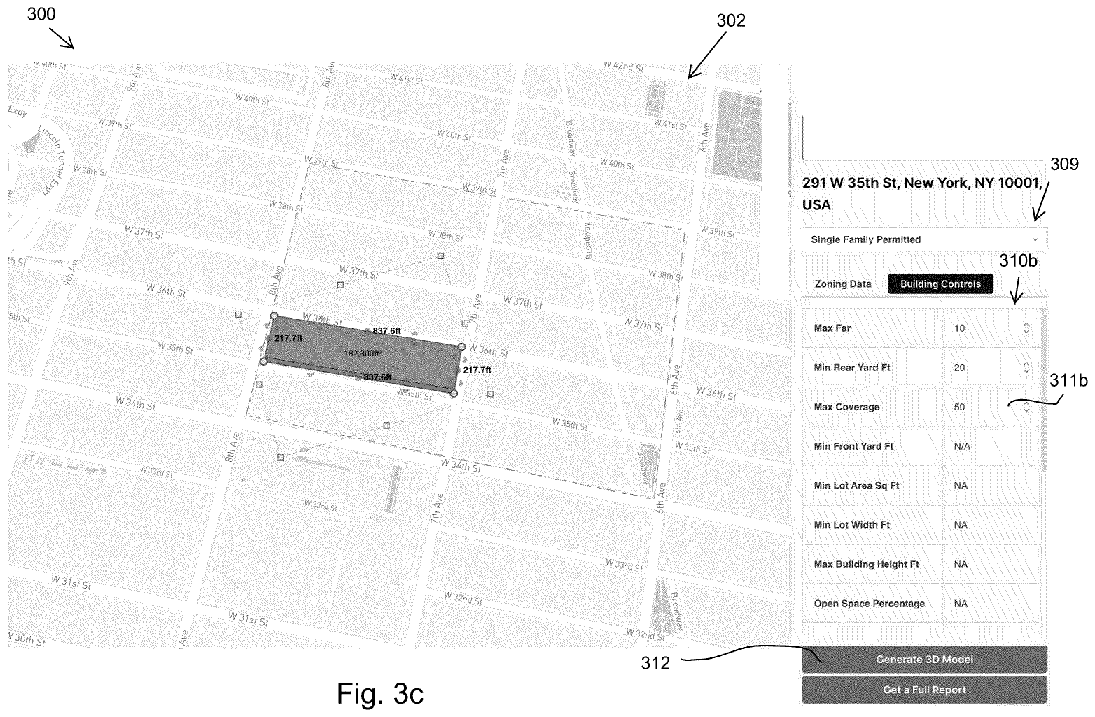

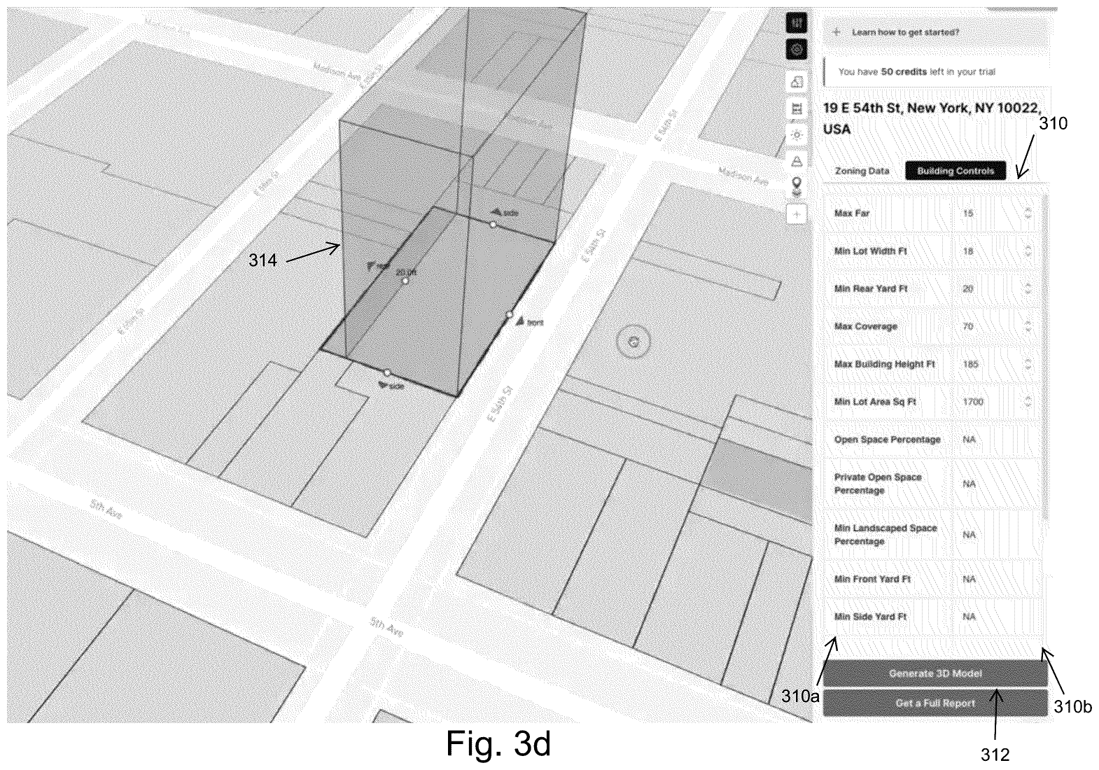

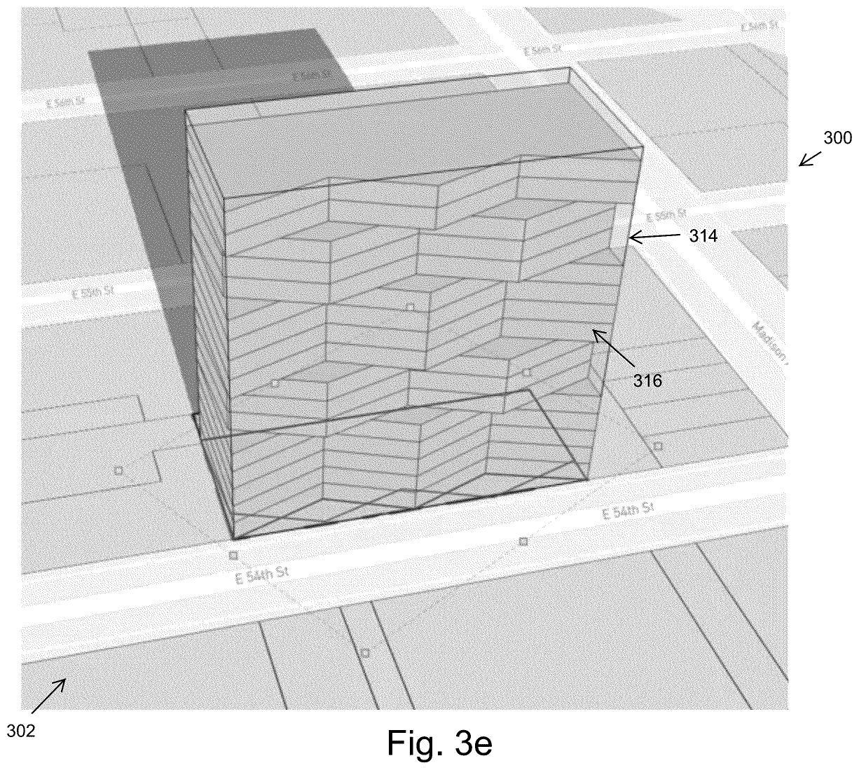

Method 200 includes a step 202 of receiving an input of selected geographic area via a graphical user interface (GUI). FIG. 3a shows an exemplary GUI 300 displayed by generative architecture model software 114 on the client computer 110 for displaying 3D map representations of geospatial data on the GUI. In one embodiment, the generative architecture model software 114 can generate representations of Geographic Information System (GIS) data on the GUI 300. The GUI 300 allows a user of client computer 110 to input a selected geographical location to generate an API call, i.e., HTTP request, that is directed to an API endpoint of server 102. The GUI can display a three-dimensional map 302 of a geographic region. The geographic region can be a region of a municipality and the map 302 can display real estate parcels 304 and the polygonal boundaries 306 delimiting each of the real estate parcels 304. As illustrated in FIG. 3a by a selected parcel 304a, the user of the client computer 110 can select a geographical area by selecting one of the real estate parcels 304 by selecting anywhere within the polygonal boundary 306 of the respective real estate parcel 304. As illustrated in FIG. 3b, the user of the client computer 110 can draw a polygon 307 onto map 302 by specifying vertices 308, corresponding to coordinates of the geospatial data displayed on map 302, anywhere within the displayed geographic region to select a geographical area. The drawn polygon does not have to be drawn on any one parcel, and can be draw on part of a parcel, an area spanning multiple parcels, or an area that has not be parceled. Alternatively, the user of client computer 110 can enter the address of a real estate parcel 304 in text form.

The selected geographic area is sent to the API endpoint of server 102 in a predefined data exchange format, which can for example be JSON format, using HTTP communication protocols. The selected geographic area can be sent as geospatial boundary coordinates for the selected geographic area.

Next, in response to the input of the selected geographic area, method 200 includes a step 204 of receiving, by the server 102 and via the API, a zoning restrictions request from the client computer 110 generated by the user interacting with the GUI 300 displayed on the client computer by the generative architecture model software 114. The zoning restrictions request can a HTTP request directed to the API endpoint of the server 102.

In response to the request, the server 102 can identify zoning data in zoning record database 108 associated with the selected geographic area in memory 104. This can include accessing, by the processor 103, a zoning data record, from the zoning record database 108 in the memory 104, associated with the selected geographic area. The zoning data record associates a zone in which the selected geographic area is located with zoning restriction attributes limiting real estate development within the zone. The processor 103 can then identify the zone, from amongst a plurality of zones in the memory 104, having a boundary defined by geospatial boundary coordinates in which the received boundary geospatial coordinates for the selected geographic area are located, and access the zoning data record associated with the zone in the memory 104.

The zoning data record in zoning record database 108 further associates the zoning restriction attributes with zoning use class information for the zone and zoning restriction parameters for the zoning restriction attributes for each of the zoning use classes. For example, a zoning restriction attribute of minimum lot area (in square feet), is associated with multiple use classes (e.g., single family dwelling, two family dwelling, multi-family dwelling) each with a different zoning restriction parameter (e.g., 5000 for single family dwelling, 8000 feet for two family dwelling, 43560 feet for multi-family dwelling, 43560 as the default).

The zoning restriction attributes and zoning restriction parameters associated with the selected geographic area in the memory are then extracted from the memory 104 by the processor 103 and converted into the predefined data exchange format. As shown in FIG. 3b, GUI 300 includes a zoning use class section window 309 that allows a user to select a zoning use class. When no zoning use class is selected, the server 102 sets the zoning use classes as default. Because the selected geographic area was selected without a selected zoning use class, the processor 103 considers the zoning use class to be default, and retrieves the zoning restriction parameters for each of the zoning restriction attributes associated with a default use class in zoning records database 108. The default zoning restriction parameter is set as either the smallest or largest from amongst all of the zoning restriction parameters associated with respective zoning restriction attributes. Referring back to the example in the prior paragraph, the default zoning restriction parameter for minimum lot area is 43560 square feet. Once in the predefined data exchange format, the relevant data is sent to the client computer 110 over HTTP for parsing and rendering as a visual representation on the GUI 300. Here, the relevant data are the zoning restriction attributes associated with the selected geographic area, and the default zoning restriction parameters associated with each zoning restriction attribute.

The zoning restriction attributes associated with the zone and the zoning restriction parameters for the zoning restriction attributes are extracted from the zoning data record in zoning record database 108, by the processor, as a function of the zoning restriction request and as a function of a default zoning use class. This can be performed by retrieving, from the zoning data record, the zoning restriction attributes associated with the zone in the zoning data record and each zoning restriction parameter for the default zoning use class associated with the zoning restriction attributes in the zoning data record.

The extracting of the relevant zoning restriction parameters can include inputting a selected conditional zoning use class into a decision tree to identify, from amongst a plurality of zoning restriction parameters corresponding to the plurality of zoning restriction attributes, the zoning restriction parameters applicable to the zoning use class associated with the selected geographic area for the zoning restriction attributes.

The zoning restriction attribute data can include a plurality of zoning restriction attribute terms that define a building envelop for constructing a building on the real estate parcel corresponding to the selected geographic area. Table 1 below shows a plurality of example zoning restriction attribute terms and their corresponding description, with examples zoning restriction parameters shown in parentheses.

TABLE 1

| | Description - (and, e.g., Zoning Restriction |
|---|---|
| Zoning Restriction Attribute Term | Parameters) |
| min_lot_area_sq_ft | Minimum lot size in square feet that a lot |
| | must be for subdivision to be approved |
| | according to the zone. |
| min_lot_width_ft | Minimum lot width in feet that a lot must be |
| | for a subdivision to be approved according to |
| | the zone. (E.g., ‘75’, ‘NA’). |
| max_building_height_ft | Maximum building height that a building can |
| | be erected according to the zone. (E.g., ‘30’, |
| | ‘NA’). |
| max_far | Maximum floor area ratio - the ratio of the |
| | total gross floor area of the structure(s) to the |
| | area of the lot permitted according to the |
| | zone. (E.g., ‘0.5’, ‘NA’). |
| max_coverage | Maximum lot coverage is the percent of the |
| | total lot that can be covered by buildings |
| | according to the zone. (E.g., ‘50’ = 50%, |
| | ‘NA’) |
| max_impervious_coverage_percentage | Maximum impervious coverage is the percent |
| | of the total lot that can be covered by building |
| | and impervious surfaces according to the |
| | zone. (E.g., ‘60’ = 60%, ‘NA’) |
| min_front_yard_ft | Front setback means the required distance that |
| | a development must be setback from a front |
| | lot line according to the zone. (E.g., ‘10’, |
| | ‘NA’) |
| min_side_yard_ft | Side setback means the required distance that |
| | a development must be setback from a side lot |
| | line according to the zone. (E.g., ‘5’, ‘NA’) |
| min_side_yard_at_least_one_ft | Side setback means the required distance that |
| | a development must be setback from at least |
| | one side lot line according to the zone. (E.g., |
| | ‘5’, ‘NA’) |
| min_side_yard_both_ft | Side setback means the required distance that |
| | a development must be setback in aggregate |
| | from both sides of the lot line according to the |
| | zone. (E.g., ‘12’, ‘NA’) |
| min_rear_yard_ft | Rear setback means the required distance that |
| | a development must be setback from a rear lot |
| | line according to the zone. (E.g., ‘10’, NA’) |
| min_landscaped_space_percentage | Minimum landscaped space is the minimum |
| | percent of the total lot that must provide green |
| | space or landscaping according to the zone. |
| | (E.g., ‘25’ = 25%, ‘NA’) |
| open_space_percentage | The minimum open space is the minimum |
| | percent of the total lot that must provide open |
| | space according to the zone. |
| | (E.g., ‘35’ = 35%, ‘NA’) |

Upon receiving the zoning restriction attributes and corresponding zoning restriction parameters in the predefined data exchange format, the client computer 110 or cloud server 112 parses in memory the zoning restriction attributes and corresponding zoning restriction parameters in the predefined data exchange format and, as shown in FIG. 3b, renders, in a control section 310 of the GUI 300, which is offset from the map 302, a column 310a displaying the zoning restriction attributes and a column 310b displaying corresponding zoning restriction parameters. Each column 310a, 310b displays a plurality of respective icons 311a, 311b, with each icon 311a representing a zoning restriction attribute and each icon 311b representing a zoning restriction parameter that is aligned with the corresponding zoning restriction attribute. Icons 311b are configured to allow zoning restriction parameters to be modified by the user selecting the corresponding icon 311b for the zoning restriction parameter and entering a new parameter, allowing the user to then visualize a building envelope that is possible if a zoning use variance is obtained.

The relevant data sent in step 204 can also include the conditional zoning use classes associated with the selected geographic location. Referring back to the above example, the conditional zoning use classes associated with selected geographic location, via association of the conditional zoning use classes to the zone in which the selected geographic location is located, are single family dwelling, two family dwelling, and multi-family dwelling.

Next, method 200 includes a step 206 of receiving an input of a conditional zoning use class for the selected geographic area via GUI 300. As discussed with respect to FIG. 3b, the user can enter a conditional use class via class section window 309 on GUI. As shown in FIG. 3c, the conditional zoning use class of single family dwelling has been selected via class section window 309.

The conditional zoning use class sent in step 204 can be displayed to the user via a dropdown menu of class section window 309 on the GUI 300 for selection by the user. The input of the conditional zoning use class can generate a conditional zoning use class API call in HTTP form that is directed to a zoning use class API endpoint of server 102. The selected conditional zoning use class is sent to the API endpoint of server 102 in the predefined data exchange format using HTTP communication protocols.

Next, in response to the input of the conditional use, method 200 includes a step 208 of receiving, by the server 102, the HTTP request directed to the zoning use class API endpoint of the server 102, and identifying zoning restriction attributes and parameters associated with the selected geographic area in memory 104 by parsing a data object, in the predefined data exchange format, in the zoning record database 108, to extract by the processor 103, zoning restriction attributes and parameters assigned to the selected geographic location for the conditional use input via the client computer 110.

The zoning restriction attributes and zoning restriction parameters associated with the selected geographic area in the memory for the selected conditional zoning use class are then extracted from the memory 104 by the processor 103 and converted into the predefined data exchange format. Referring back to the example for minimum lot area, if single family dwelling is selected by the user as the conditional zoning use class, the zoning restriction parameter for zoning restriction attribute of minimum lot area is 5000 square feet. Once in the predefined data exchange format, the relevant data is sent to the client computer 110 over HTTP for parsing and rendering as a visual representation on the GUI 300. Here, the relevant data are the zoning restriction attributes associated with the selected geographic area, and the default zoning restriction parameters associated with each zoning restriction attribute.

The zoning restriction attributes associated with the zone and the zoning restriction parameters for the zoning restriction attributes are extracted from the zoning data record in zoning record database 108, by the processor 103, as a function of the zoning restriction request and as a function of a default zoning use class. This can be performed by retrieving, from the zoning data record, the zoning restriction attributes associated with the zone in the zoning data record and each zoning restriction parameter for the default zoning use class associated with the zoning restriction attributes in the zoning data record.

The extracted zoning restriction attributes and zoning restriction parameters are then packaged into a data object in the predefined data exchange format associated with the API, and transmitted as an API response to the generative architecture model software 114 over HTTP for parsing and rendering as a visual representation on the GUI 300.

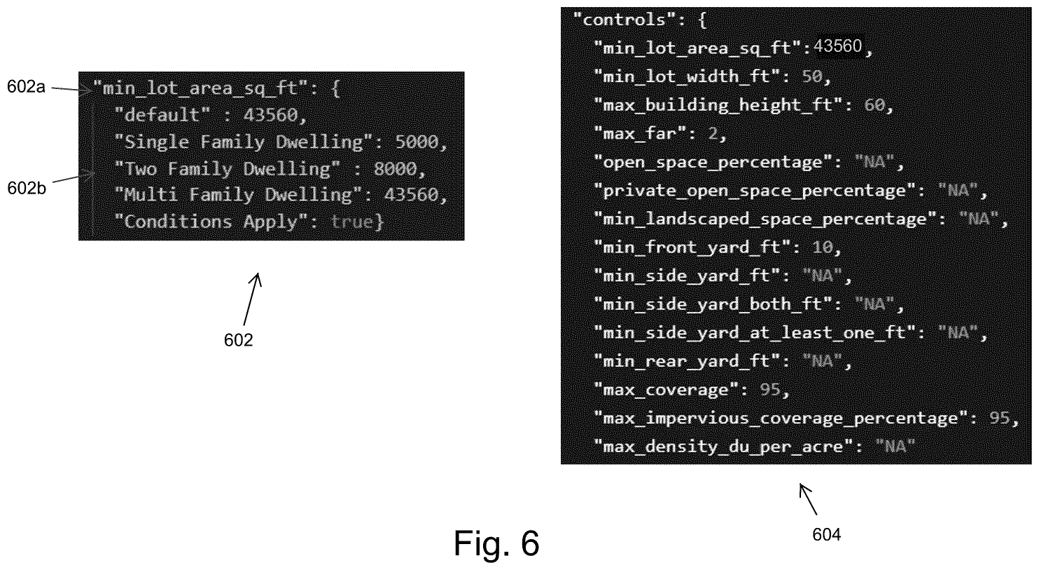

As illustrated by an example zoning data record format 602 in FIG. 6, each zoning data record in zoning record database 108 can be in a nested format in which each zoning restriction attribute is a parent element 602a and all of the zoning use classes and the zoning restriction parameters applicable to the zoning use class associated with the selected geographic area for the zoning restriction attributes are stored as child elements 602b of the respective zoning restriction attribute. During the extracting by the processor 103, the decision tree can filter through each zoning restriction attribute and find the child elements 602b associated with the selected conditional zoning use class. All of the zoning restriction attributes associated with the zone of the selected geographic area and the corresponding zoning restriction parameters associates with the selected conditional zoning use class can be packaged into a data object in an example predefined data exchange format 604 in FIG. 6.

Upon receiving the zoning restriction attributes and parameters in the predefined data exchange format, the client computer 110 or the cloud server 112 running the generative architecture model software 114 parses in memory the zoning restriction attributes and parameters in the predefined data exchange format and renders the zoning restriction attributes and parameters in the control section 310 of the GUI 300. By comparing FIGS. 3b and 3c, the selection of the conditional zoning use class of single family dwelling modifies the zoning restriction parameters generated in icons 311b of column 310b in FIG. 3c compared to the zoning restriction parameters generated in icons 311b of column 310b in FIG. 3b. These zoning use class specific zoning restriction attributes and parameters are modifiable via the control section 310 until the user is satisfied with the zoning restriction parameters.

Then, in a step 210, user can select an icon 312 (FIG. 3c) on the GUI 300 to send a 3D model request in the form of a 3D model API call to the server 102 to generate a 3D building envelope on the selected geographic location. The 3D model API call transmits the zoning restriction attributes and parameters packaged into the data object in the predefined data exchange format to a 3D model API endpoint of server 102. It will be appreciated that step 210 can also be performed immediately after step 204 to send a 3D model request for the zoning restriction attributes and parameters associated with the default zoning use class.

In response, method 200 next includes a step 210 of receiving, via the API, the 3D model request from the client computer generated by the user interacting with the GUI 300 displayed on the client computer 110 by the generative architecture model software 114. The 3D model request can include a request for a 3D model of a building envelope delimited by the relevant zoning restriction parameters for the selected geographic area. The relevant zoning restriction parameters delimiting the building envelope can be as transmitted to the generative architecture model software 114 in the data object in step 208, or as further modified by the user of the client computer via the control section 310 of the GUI 300. The 3D model request can also include geospatial boundary coordinates and a geospatial origin coordinate for the selected geographic area, in a format defined by the generative architecture model software 114.

As described above with respect to Table 1, the zoning restriction parameters delimiting the building envelope are for zoning restriction attributes defining a height of the building envelope, a width of the building envelope, a depth of the building envelope and an area of the building envelope.

For example, the zoning restriction attributes defining a depth of the building envelope can include a setback from a front lot line and a setback from a rear lot line; the zoning restriction attributes defining a width of the building envelope can include a side setback from a side lot line, a minimum lot width; the zoning restriction attributes defining a height of the building envelope can include a maximum building height and a maximum floor area ratio; and the zoning restriction attributes defining an area of the building envelope can include a minimum lot size, a maximum lot coverage, a maximum impervious coverage, a minimum landscaped space and a minimum open space.

Next, a step 212 is performed by server 212 to generate 3D building envelope geospatial data for display on the client computer 110. Step 212 includes processing the received 3D model request, by the processor 103, and transmitting the requested 3D model of the building envelope to the generative architecture model software 114 to generate a 3D geospatial data layer on the GUI 300 on the 3D geospatial representation of the selected geographic area. The building envelope can include x, y and z coordinates representing an exterior of a possible building that can be built on the geographic area and a number of floors of the possible building.

Step 212 includes a plurality of substeps, and can include a first substep of transforming the geospatial boundary coordinates to local coordinates for feasible processing when the server 102 stores geospatial data in a different coordinate system than generative architecture model software 114.

In a second substep, the geospatial origin coordinate is scaled to (0,0). The origin coordinate can be the centroid for an anchor position from where the 3D model representing the building envelope is centered.

Step 212 then includes a third substep of generating x and y coordinates (for the building envelope based on the transformed geospatial boundary coordinates of the selected geographic area and zoning restriction attributes defining the width of the building envelope, the depth of the building envelope and the area of the building envelope. The front, rear and setbacks specified by the zoning restriction attributes and the zoning restriction parameters can first be applied to the transformed geospatial boundary to generate initial x and y coordinates. Next, the initial x and y coordinates are modified by the coverage area and the maximum floor area ratio specified by the zoning restriction attributes and the zoning restriction parameters.

A fourth substep of step 212 includes generating z coordinates and a number of floors for the building envelope based on the transformed geospatial boundary coordinates of the selected geographic area and zoning restriction attributes defining the height of the building envelope. This can include calculating the number of floors by either using the maximum building height or, if maximum building height is not given, using the maximum floor area ratio. Each floor can have a predetermined height of for example ten feet.

Using the values from third and fourth substeps, a fifth substep is performed to generate the 3D envelope using a 3D generating software, which is run by processor 103 in memory 104.

The resulting 3D envelop is then returned in a sixth substep in a framework specified by the generative architecture model software 114, which can for example bb FLASK Python Framework. Depending on the requirements of the generative architecture model software 114, the generated 3D envelope can be in either GLTF (encoded json) or GLB (binary) formats.

Lastly, step 212 includes a seventh substep of transmitting the requested 3D model of the building envelope to the generative architecture model software 114 to generate a 3D geospatial data layer on the GUI displayed on the client computer on a 3D geospatial representation of the selected geographic area. The 3D model of the building envelope is transmitted from server 102 to client computer 110 in the required format over HTTPS protocol for rendering on the map 302 at the selected geographic location.

In a step 214, a 3D geospatial data layer of the building envelope is displayed on client computer 110 by generative architecture model software 114. Upon receipt of the 3D model of the building envelope, client computer 110 or cloud server 112 can then normalize geospatial boundary coordinates and the geospatial origin coordinates based on the coordinate system being used by the generative architecture model software 114, and as illustrated in FIG. 3d, the 3D building envelope model 314 is rendered on the map 302 by using the normalized geospatial boundary coordinates and the geospatial origin coordinates. The 3D building envelope model 314 can include five planes that illustrate zoning restriction attributes and parameters that can limit real estate development, with the sixth plane of the 3D building envelope model 314 being aligned on the selected geographic area. The five planes represent the front, sides, rear and roof of the building. As illustrated in FIG. 3d, the control section 310 illustrates the zoning restriction attributes and parameters defining the 3D building envelope model 314 while visualizing the d building envelope model 314. The zoning restriction parameters in column 310b can then be further modified by the user, and a new 3D building envelope model 314 can generated by selecting icon 312, enhancing the use of generative architecture model software 114 to allow the user to explore different building designs.

As illustrated in FIG. 3e, the 3D building envelope model 314 can remain on the GUI 300 while the user modifies features of a 3D building model 316 on map 302. Th the 3D building envelope model 314 can be used by user of the client computer 110 or cloud server 112 to provide guidelines for designing the building on the geographic area.

The digitized zoning data in the memory 104 of server 102, which can be formatted into the zoning data record using in method 200 can be created from government zoning codes and government zoning maps. Local governments adopt official zoning codes that are currently published in paper or unstructured digital formats. These zoning codes outline the zoning restrictions that apply within a jurisdiction. Zoning codes reference a zoning map to apply the zoning restrictions to a property parcel or block of property parcels.

Local governments publish these zoning maps in paper or digital image formats. These maps are the official, source for determining zoning restrictions. The zoning map delineates a zoning designation to a property parcel or a block of property parcels from among a limited set of possible designations.

For example, a property or a block of property parcels designated “R-1 Single Family” on a zoning map and a zoning code is identified as an appropriate location for single family residential dwellings to be constructed. A property or a block of property parcels designated “R-4 Multi-Family” on a zoning map and a zoning code is identified as an appropriate location for a multi-family residential building to be constructed.

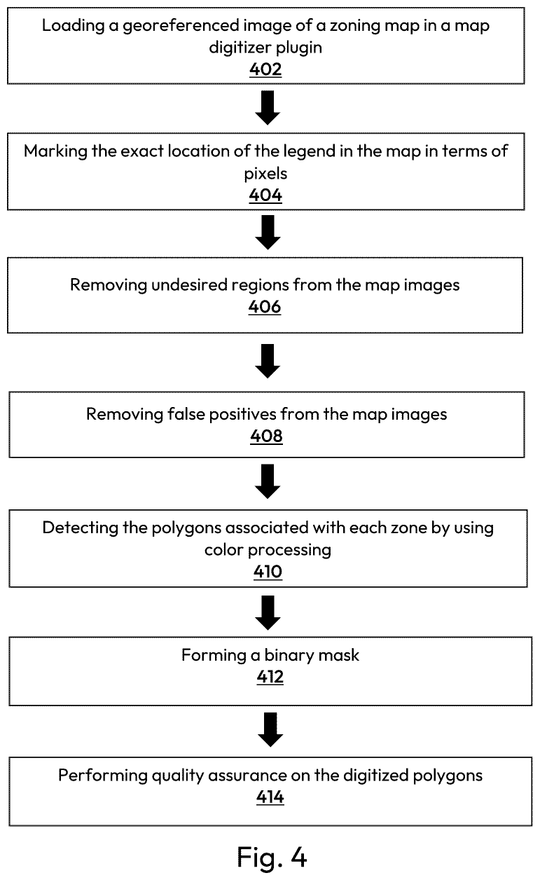

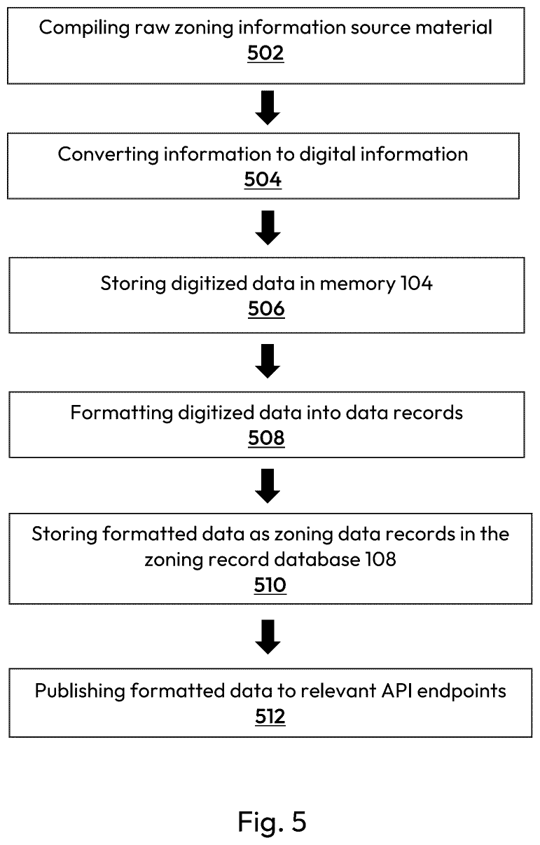

Methods 400 and 500 discussed below can be performed to generate the zoning records database 108 used in method 200. First, the method 400 of generating the digitized zoning data from the government zone maps shown in FIG. 4 is performed for a municipality, then the method 500 of generating the digitized zoning data from the government zone codes shown in FIG. 5 is performed. The method 400 converts each zone from the government zone maps into geospatial coordinates, and associates each zone with a zone code. The method 500 then extracts zoning use classes, the zoning restriction attributes and the zoning restriction parameters for each zone code, and associates the zoning use classes, the zoning restriction attributes and the zoning restriction parameters with a respective zone, and the geospatial coordinates of the zone.

The method 400 includes a first step 402 of loading a georeferenced image of a zoning map in a map digitizer plugin. The georeferenced image is then usable for GIS related processing. An unreferenced copy of the same image is then stored to perform the tasks related to computer vision and deep learning because the georeferenced images not only increase the computational complexity but most of the libraries are unable to process this format.

A next step 404 is marking the exact location of the legend in the map in terms of pixels. This marked region is used to identify and extract the legend of the map based on deep learning-based optical character recognition (OCR). The model used for performing text recognition is trained on English text. The map legend usually contains three entities, namely zone code, zone names, and corresponding zone colors. The zone codes and zone names are extracted using OCR. In order to detect the color associated with the zone, a shape detection is performed as the colors can be represented using arbitrary shapes, such as rectangles, circles, ovals, and other irregular shapes. After the successful completion of shape detection, the color of the shape is estimated and and saved. In case a wrong color is detected, an option is provided to correct the zone color manually.

A next step 406 is removing undesired regions from the map images. In order to reduce the computational complexity and increase the accuracy of the system, these undesired regions are removed and an accurate map extent is detected. Regions in the image are identified that correspond to the ground truth map by using a hybrid technique developed using computer vision (such as denoising, morphological processing) and classical machine learning (such as clustering and statistical modeling). The undesired regions are removed before further processing.

A next step 408 is removing false positives from the map images. It is possible that during map extent detection, some false positives are induced in the resulting image. The false positives do not represent the part of the map. Instead, they represent the unwanted regions, such as city logos and additional text. In order to remove these false positives induced during the process of map extent detection, an optional window is provided in which the digitizer can select these unwanted regions and remove them entirely before further processing.

After cleaning, a step 410 is detecting the polygons associated with each zone by using color processing. Considering the application, the conventional segmentation methods for extracting the zones using colors are not usable. Therefore, pixel-based processing is used instead of neighborhood processing and other pre-trained models. Each pixel in the image is assigned a label by using the color information extracted during the legend extraction step. Each color available in the map can be available in the map legend in order to avoid false pixel classification.

After each pixel in the image is classified, a step 412 of forming a binary mask is performed. The binary mask further improves the boundaries by correcting the boundary pixels using computer vision techniques. Afterwards, this binary mask is consumed by the GIS algorithm to recursively digitize the polygons of each zone. The process of digitizing associates each polygon with latitude and longitude coordinates.

Finally, a step 414 of quality assurance of the digitized polygons is performed by automatically removing false coordinates, eliminating overlapping boundaries of contiguous polygons, and removing the gaps between polygons. Manual quality checks can be performed as the quality of the image significantly influences the accuracy. Therefore, few remaining artifacts and distorted boundaries are corrected by the digitizer manually.

The method 500 includes a first step 502 of compiling raw zoning information source material. Step 502 can include finding Find URLs, pdfs, and images for target cities from the internet, inputting the Input the URLs to web crawlers for extracting the HTMLs, and automatically splitting and saving the extracted HTMLs in JSON files.

A next step 504 includes converting the information from step 502 into digital information. The step 504 can include extracting the text from HTML data saved in JSONs for each html page or section of the zoning code. The extracted text is then cleaned by removing unicodes and non-desired redundant text, and formatted to remove newline characters and extra spaces using regular expressions, text tokenizers and other text processing techniques. Then, deep learning models are used for extracting the entities of interest, and a large language model (LLM) is used to enhance and format the output.

A further step 506 includes storing the digitized data from step 504 into a database, which can include pushing the digitized data into the database using an automated pipeline.

Then, in a step 508, the digitized data is formatted and stored in memory 104. Zoning restriction attributes are associated with a corresponding zone and corresponding zoning restriction parameters. A first step includes separating standard and non-standard zoning restriction attributes from each other. Standard zoning restriction attributes can include those shown in Table 1. The non-standard zoning restriction attributes are then processed to predict the category of non-standard zoning restriction attributes. For example, a category of zoning restriction attributes can be setbacks, and can include front, rear and side setbacks. Zoning restriction parameters are then inserted for each zoning restriction attributes for each zoning code, and a data object in a predefined data exchange format, for example a JSON object, is then created.

In a step 510, the formatted data is then stored as zoning data records in the zoning record database 108, for example by pushing the formatted data into the zoning record database 108 in memory 104.

A last step of method 512 then including publishing the stored formatted data to the relevant API endpoints.

What is claimed is:

1. A method of presenting structured digitized zoning data, by a server including a processor and a memory, via an application programming interface (API) to a client computer for displaying three-dimensional (3D) representations of geospatial data generated by generative architecture model software 114 on a graphical user interface (GUI) on the client computer, the method comprising:
receiving, by the server and via the API, a zoning restrictions request from the client computer generated by a user interacting with the GUI displayed on the client computer by the generative architecture model software 114, the zoning restrictions request including a selected geographic area;
accessing, by the processor, a zoning data record, from a zoning record database in the memory, associated with the selected geographic area,
the zoning data record associating a zone in which the selected geographic area is located with zoning restriction attributes limiting real estate development within the zone,
the zoning data record further associating the zoning restriction attributes with zoning use class information for the zone and zoning restriction parameters for the zoning restriction attributes; and
extracting from the zoning data record, by the processor, as a function of the zoning restriction request and as a function of a default and/or a conditional zoning use class, the zoning restriction attributes associated with the zone and the zoning restriction parameters for the zoning restriction attributes by retrieving, from the zoning data record, the zoning restriction attributes associated with the zone in the zoning data record and each zoning restriction parameter for the default and/or conditional zoning use class associated with the zoning restriction attributes in the zoning data record;
packaging, by the processor, the extracted zoning restriction attributes and zoning restriction parameters into a data object in a predefined data exchange format associated with the API; and
transmitting, by the processor, the data object, as an API response, to the generative architecture model software to generate a visual representation of the extracted zoning restriction parameters on the GUI on the client computer.

2. The method as recited in claim 1 further comprising:
receiving, by the server and via the API, a 3D model request from the client computer generated by the user interacting with the GUI displayed on the client computer by the generative architecture model software, the 3D model request including a request for a 3D model of a building envelope delimited by the zoning restriction parameters for the selected geographic area; and
processing the received 3D model request, by the processor, and transmitting the requested 3D model of the building envelope to the generative architecture model software to generate a 3D geospatial data layer of the building envelope on the GUI displayed on the client computer on a 3D geospatial representation of the selected geographic area.

3. The method as recited in claim 2 wherein the zoning restriction parameters delimiting the building envelope are for zoning restriction attributes defining a height of the building envelope, a width of the building envelope, a depth of the building envelope and an area of the building envelope.

4. The method as recited in claim 3 wherein the zoning restriction attributes defining a depth of the building envelope include zoning restriction attributes selected from a group consisting of a setback from a front lot line and a setback from a rear lot line,
the zoning restriction attributes defining a width of the building envelope include zoning restriction attributes selected from a group consisting of a side setback from a side lot line, and a minimum lot width,
the zoning restriction attributes defining a height of the building envelope include zoning restriction attributes selected from a group consisting of a maximum building height, and a maximum floor area ratio,
the zoning restriction attributes defining an area of the building envelope include zoning restriction attributes selected from a group consisting of a minimum lot size, a maximum lot coverage, a maximum impervious coverage, a minimum landscaped space and a minimum open space.

5. The method as recited in claim 2 wherein the receiving of the 3D model request includes receiving, by the server, as part of the 3D model request, the relevant zoning restriction parameters delimiting the building envelope, as transmitted to the generative architecture model software in the data object, or as further modified by the user of the client computer via the GUI.

6. The method as recited in claim 5 wherein the receiving of the received 3D model request includes receiving, by the server, as part of the 3D model request, the selected geographic area.

7. The method as recited in claim 6 wherein the selected geographic area is in the form of geospatial boundary coordinates and a geospatial origin coordinate,
the processing of the received 3D model request including transforming the geospatial boundary coordinates to local coordinates.

8. The method as recited in claim 1 wherein the receiving of the zoning restrictions request from the client computer includes receiving geospatial boundary coordinates for the selected geographic area.

9. The method as recited in claim 8 wherein the geospatial coordinates are generated by the user drawing a polygon on a 3D geospatial representation of a geographic region displayed by the generative architecture model software on the GUI or by selecting a real estate parcel displayed on the 3D geospatial representation of a geographic region.

10. The method as recited in claim 8 wherein the accessing of the zoning data record associated with the selected geographic area includes:
identifying, by the processor, the zone, from amongst a plurality of zones in the memory, having a boundary defined by geospatial boundary coordinates in which the received boundary geospatial coordinates for the selected geographic area are located; and
accessing the zoning data record associated with the zone in the memory.

11. The method as recited in claim 1 wherein the extracting of the zoning restriction parameters includes to identifying, from amongst a plurality of zoning restriction parameters corresponding to the zoning restriction attributes, the zoning restriction parameters applicable to the zoning use class associated with the selected geographic area for the zoning restriction attributes.

12. The method as recited in claim 11 wherein the zoning data record is in a nested format in which each zoning restriction attribute is a parent element and all of the zoning use classes and the zoning restriction parameters applicable to the zoning use class associated with the selected geographic area for the zoning restriction attributes are stored as child elements of the respective zoning restriction attribute.

13. The method as recited in claim 12 wherein the extracting includes filtering through each zoning restriction attribute and finds the child elements associated with the selected conditional zoning use class.

14. The method as recited in claim 1 wherein the extracting from the zoning data record, by the processor, is performed as a function of the default zoning use class, the method further comprising:
sending, by the server and via the API, conditional zoning use class associated with the selected geographic area for display on the GUI of the client computer;
receiving, by the server and via the API, a selection of the one of the conditional zoning use class by the user of the client computer via the GUI;
extracting from the zoning data record, by the processor, as a function of the zoning restriction request and as a function of the selected conditional zoning use class, the zoning restriction attributes associated with the zone and conditional zoning restriction parameters for the zoning restriction attributes by retrieving, from the zoning data record, the zoning restriction attributes associated with the zone in the zoning data record and each conditional zoning restriction parameter for the conditional zoning use class associated with the zoning restriction attributes in the zoning data record;
packaging, by the processor, the conditional extracted zoning restriction parameters into a further data object in the predefined data exchange format associated with the API; and
transmitting, by the processor, the further data object, as an API response, to the generative architecture model software to generate a visual representation of the conditional extracted zoning restriction parameters on the GUI on the client computer.

15. A server presenting structured digitized zoning data, by a server including a processor and a memory, via an application programming interface (API) to a client computer for displaying three-dimensional (3D) representations of geospatial data generated by generative architecture model software on a graphical user interface (GUI) on the client computer, the server comprising:
at least one processor; and
a memory coupled to the at least one processor, the memory including software instructions executable by the at least one processor to:
receive, via the API, a zoning controls request from the client computer generated by a user interacting with the GUI displayed on the client computer by the generative architecture model software, the zoning controls request including a selected geographic area;
access a zoning data record, from a zoning record database in the memory, associated with the selected geographic area,
the zoning data record associating a zone in which the selected geographic area is located with zoning restriction attributes limiting real estate development within the zone,
the zoning data record further associating the zoning restriction attributes with zoning use class information for the zone and zoning restriction parameters for the zoning restriction attributes; and
extract from the zoning data record, as a function of the zoning restriction request and as a function of a default and/or a conditional zoning use class, the zoning restriction attributes associated with the zone and the zoning restriction parameters for the zoning restriction attributes by retrieving, from the zoning data record, the zoning restriction attributes associated with the zone in the zoning data record and each zoning restriction parameter for the default and/or conditional zoning use class associated with the zoning restriction attributes in the zoning data record;
package the extracted zoning restriction parameters into a data object in a predefined data exchange format associated with the API; and
transmit the data object, as an API response, to the generative architecture model software to generate a visual representation of the extracted zoning restriction parameters on the GUI on the client computer.

16. The system as recited in claim 15, wherein the memory including software instructions executable by the at least one processor to:
receive, via the API, a 3D model request from the client computer generated by the user interacting with the GUI displayed on the client computer by the generative architecture model software, the 3D model request including a request for a 3D model of a building envelope delimited by the relevant zoning restriction parameters for the selected geographic area; and
process the received 3D model request and transmit the requested 3D model of the building envelope to the generative architecture model software to generate a 3D geospatial data layer on the GUI displayed on the client computer on a 3D geospatial representation of the selected geographic area.

17. A method of presenting structured digitized zoning data via an application programming interface to generative architecture model software, the method comprising:
receiving, via the application programming interface, a request from the generative architecture model software including a selected geographic location;
processing the request, via a computer processor, by:
mapping to the location information to a data record including zoning restriction attributes and a zoning use class associated with the selected geographic location; and
identifying, from amongst a plurality of zoning restriction parameters, a zoning restriction parameter applicable to the zoning use class associated with the area information for each of the zoning restriction attributes; and
generating a 3D design model based on the zoning restriction parameters to be displayed via a graphical user interface.

18. A non-transitory computer-readable media storing computer-executable instructions that, when executed on a processor, cause the processor to perform the method as recited in claim 1.
